(19) United States
(12) Patent Application Publication
(10) Pub. No.: US 2024/0347420 A1
(43) Pub. Date: Oct. 17, 2024

(54) HEATSINK AND SEMICONDUCTOR DEVICE

(71) Applicant: Mitsubishi Electric Corporation, Tokyo (JP)

(72) Inventor: Hiromichi MIURA, Tokyo (JP)

(73) Assignee: Mitsubishi Electric Corporation, Tokyo (JP)

(21) Appl. No.: 18/409,602

(22) Filed: Jan. 10, 2024

(30) Foreign Application Priority Data
Apr. 12, 2023 (JP) 2023-065231

(51) Int. Cl. H01L 23/40

(52) U.S. Cl. CPC H01L 23/4006; H01L 2023/4087

(57) ABSTRACT

A heatsink of the present disclosure includes a base having a heat dissipation surface that is thermally coupled to a heating element and dissipates heat from the heating element and a screw hole provided on the heat dissipation surface, and a screw screwed into the screw hole. A semiconductor device of the present disclosure includes the heatsink and a semiconductor module as the heating element.

### BACKGROUND OF THE INVENTION

### Field

The present disclosure relates to a heatsink and a semiconductor device with the heatsink.

### Background

A technique of fixing a heatsink at a semiconductor module with a heat dissipation sheet, grease, or the like, and dissipating heat generated from the semiconductor module is known.

JP 2006-114688 A discloses a heatsink capable of easily adjusting heat dissipation characteristics. In JP 2006-114688 A, a plurality of arrays of concave pin insertion portions are formed on a surface side of a base portion of a metal plate, and base end portions of pin fins are respectively inserted into and fixed at the pin insertion portions to vertically arrange a plurality of pin fins on the base portion.

In the above-described method in which pin fins and a base are fixed with fixtures, stability of the fins becomes an issue. Further, even if the pin fins are pressed into the base by a press fitting machine without using fixtures, substantial press-in force is required to reliably press the plurality of pin fins into the base. Also in a case where the pin fins are fixed with solder, or the like, it requires work of soldering.

### SUMMARY

To solve the above-described problem, a first object of the present disclosure is to provide a heatsink capable of easily adjusting heat dissipation characteristics and capable of easily and reliably fixing fins and a base.

Further, a second object of the present disclosure is to provide a semiconductor device capable of easily adjusting heat dissipation characteristics and capable of easily and reliably fixing fins and a base.

The features and advantages of the present disclosure may be summarized as follows.

According to an aspect of the present disclosure, a heatsink comprises a base having a heat dissipation surface that is thermally coupled to a heating element and dissipates heat from the heating element, and a screw hole provided on the heat dissipation surface; and a screw screwed into the screw hole.

According to an aspect of the present disclosure, a heatsink comprises a base having a heat dissipation surface that is thermally coupled to a heating element and dissipates heat from the heating element, and a groove provided on the heat dissipation surface; and a screw whose screw head is inserted into the groove and whose screw tip portion projects from the heat dissipation surface.

According to an aspect of the present disclosure, a heatsink comprises a base having a heat dissipation surface that is thermally coupled to a heating element and dissipates heat from the heating element, and a nut insertion portion provided on the heat dissipation surface; a nut inserted into the nut insertion portion; and a screw screwed into the nut so that a screw head projects from the heat dissipation surface.

Other and further objects, features and advantages of the invention will appear more fully from the following description.

### BRIEF DESCRIPTION OF DRAWINGS

FIG. 1 is a side view illustrating a heatsink according to a first embodiment of the present disclosure.

FIG. 2 is a top view illustrating the heatsink according to a second embodiment of the present disclosure.

FIG. 3 is a top view illustrating the heatsink according to a third embodiment of the present disclosure.

FIG. 4 is a side view illustrating the heatsink according to a fourth embodiment of the present disclosure.

FIG. 5 is a configuration diagram illustrating a semiconductor device in related art according to a comparative example of the present disclosure.

FIG. 6 is a configuration diagram illustrating a semiconductor device according to a fifth embodiment of the present disclosure.

### DESCRIPTION OF EMBODIMENTS

A heatsink and a semiconductor device according to embodiments of the present disclosure will be described with reference to the drawings. The same reference numerals will be assigned to the same or corresponding components, and repetitive description will be omitted.

### First Embodiment

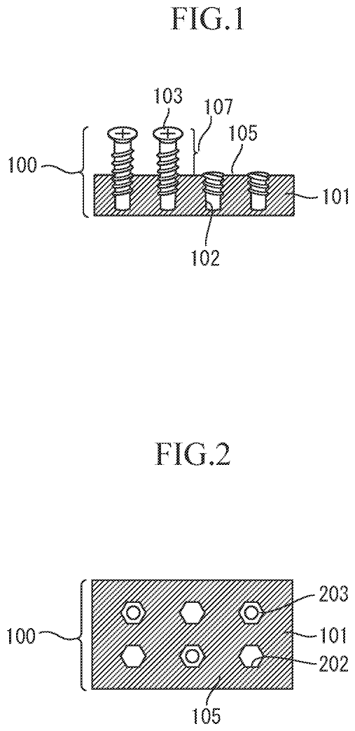

FIG. 1 is a side view illustrating a heatsink 100 according to a first embodiment of the present disclosure. As illustrated in FIG. 1, the heatsink 100 includes a base 101 and screws 103.

A heat dissipation surface 105 is a surface that dissipates heat from a heating element that is thermally coupled to the heatsink 100. A plurality of screw holes 102 are provided on the heat dissipation surface 105. While a shape of the screw hole 102 is no object, it is preferable to use the screw hole 102 conforming to typical screw standards in terms of manufacturing cost to use a commercially available screw 103. Note that the screw hole 102 does not have to be a through-hole and may be a blind hole.

In the screw 103 inserted into the screw hole 102, a projecting portion 107 that projects from the heat dissipation surface 105 plays a role of a heat dissipation fin. By changing a length, a shape, the number, a material, or the like, of the screw 103, heat dissipation characteristics of the heatsink 100 can be adjusted.

In the heatsink 100, heat dissipation can be improved by concentratively positioning the screw holes 102 at locations where heat dissipation is particularly required to increase density of the screws 103 in accordance with heat generation of the heating element. Here, the density of the screws 103 refers to the number of screws 103 per unit area of the heat dissipation surface 105. Alternatively, heat dissipation of the heatsink 100 can also be improved by screwing a long screw 103. By measuring heat dissipation characteristics of the screw 103 itself as a function of a length, a radius, the number, a material, or the like, in advance, density and a length of the screw 103 required for heat dissipation can be obtained using the measurement value and temperature distribution of the heatsink 100.

As described above, the heatsink 100 in the present embodiment can reliably fix fins and the base 101 only by the screws 103 as the fins being screwed into the screw holes 102. In fixing, solder, a fixture, or the like, is not required. The fins are reliably fixed at the base 101 through screwing, and thus, the heatsink 100 has sufficient quality as a mass-produced product.

### Modified Example of the First Embodiment

Note that while FIG. 1 illustrates a state where the screws 103 are screwed into part of the plurality of screw holes 102, there may be one screw hole 102, and if the screw 103 is screwed into the one screw hole 102, effects similar to the above can be obtained. Note that this point is also common to all the following embodiments.

Further, a shape of the screw 103 is not limited to the shape illustrated in FIG. 1 and only requires to be a shape that is to be screwed into the screw hole 102 provided at the base 101 through screwing. Note that this point is also common to all the following embodiments.

Further, in the example in FIG. 1, the screw 103 has such a configuration that does not contact other members except the base 101 to increase a surface area of heat dissipation. In this configuration, by reflecting only heat dissipation characteristics of the screw 103 itself, heat dissipation characteristics of the heatsink 100 can be strictly adjusted. However, the screw 103 may contact other members. For example, by allowing a tip of the screw to pass through from the base so as to contact a heat dissipation sheet, or the like, heat dissipation can be further improved. Note that this point is also common to all the following embodiments.

Further, in the example in FIG. 1, a screw head of the screw 103 has such a configuration that projects from the heat dissipation surface 105 and does not contact the heat dissipation surface 105. However, in a case where the screw hole 102 is a through-hole, or the like, the screw 103 may be inserted from a back surface side of the heat dissipation surface 105. In this case, not the screw head, but a screw tip portion projects from the heat dissipation surface 105 and plays a role of a heat dissipation fin as the projecting portion 107. Note that this point is common to all the following embodiments.

### Second Embodiment

FIG. 2 is a top view illustrating the heatsink 100 according to a second embodiment of the present disclosure. In the present embodiment, the screw holes 102 in the first embodiment are changed to nut insertion holes 202 and nuts 203.

In other words, in the present embodiment, the heatsink 100 includes the base 101, a plurality of nut insertion holes 202 provided on the heat dissipation surface 105 provided at the base 101, one or more nuts 203 inserted into the nut insertion holes 202, and screws 103 screwed into the nuts 203.

In FIG. 2, the screws 103 are not illustrated to make it easier to understand changes from the first embodiment. Note that also in all the following embodiments, the screws 103 will not be illustrated unless otherwise necessary.

In the heatsink 100 in the present embodiment, by inserting the nuts 203 into the nut insertion holes 202 and screwing the screws 103, heat can be dissipated from the projecting portions 107 of the screws 103 in a similar manner to the first embodiment. This can provide effects similar to those in the first embodiment. Further, this eliminates the need to provide the screw holes 102 at the base 101 in advance, so that it is possible to achieve lower manufacturing cost than that in the first embodiment.

### Modified Example of the Second Embodiment

Note that in FIG. 2, the number and arrangement of the nut insertion holes 202 are one example and are not limited to those. There may be one nut insertion hole 202 and one nut 203, and if the screw 103 can be screwed into the one nut 203, effects similar to the above can be obtained. Further, while a shape of the nut insertion hole 202 viewed from the top view in FIG. 2 is preferably a hexagonal shape that is the same as the nut 203 to prevent rotation of the nut 203, the shape only requires to be a shape that allows insertion of the nut 203 and may be a circle. Note that these points are also common to all the following embodiments.

Further, the screws 103 are preferably screwed into the nuts 203 so as not to contact other members except the nuts 203 to increase a surface area of heat dissipation. However, as described in the first embodiment, the screws 103 may contact other members.

Further, in a similar manner to the first embodiment, the nut insertion holes 202 may be concentratively positioned at locations where heat dissipation is particularly required to increase density of the screws 103.

### Third Embodiment

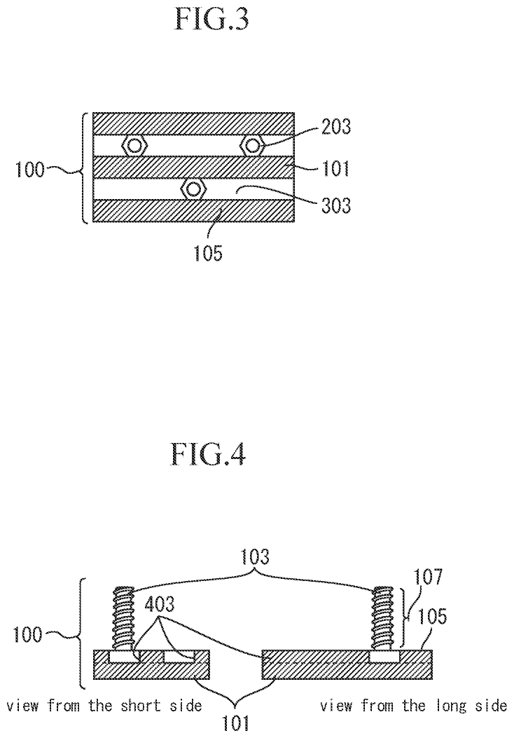

FIG. 3 is a top view illustrating the heatsink 100 according to a third embodiment of the present disclosure. In the present embodiment, the nut insertion holes 202 in the second embodiment are changed to a nut insertion groove 303.

The nut insertion groove 303 is a groove into which a plurality of nuts 203 can be inserted. While a shape of the nut insertion groove 303 is no object, the nut insertion groove 303 preferably has a size conforming to a size of a typical nut 203 in terms of manufacturing cost to enable use of a commercially available nut 203.

In the present embodiment, flexibility can be provided to positions where the nuts 203 are inserted in a groove direction, in addition to the effects described in the second embodiment. This results in providing flexibility to positions of the screws 103 that play a role of the heat dissipation fins. Further, it becomes easier to concentratively position the nuts 203 at locations where heat dissipation is particularly required to increase density of the screws 103.

Further, in terms of manufacturing, forming a groove is easier than forming a plurality of the screw holes 102 and the nut insertion holes 202. By this means, processing cost and a work period can be reduced.

### Fourth Embodiment

FIG. 4 is a side view illustrating the heatsink 100 according to a fourth embodiment of the present disclosure. In the present embodiment, the nut insertion groove 303 in the third embodiment is changed to a screw insertion groove 403.

The screw insertion groove 403 is a groove into which a plurality of screw heads of the screws 103 can be inserted. While a shape of the screw insertion groove 403 is no object, the screw insertion groove 403 preferably has a size conforming to a size of a typical screw head in terms of manufacturing cost to enable use of a commercially available screw 103.

In the present embodiment, screw tip portions of the screws 103 inserted into the screw insertion groove 403 project from the heat dissipation surface 105 and play a role of the heat dissipation fins as the projecting portions 107. Such a structure provides flexibility to positions of the screws 103 in a groove direction compared to the first embodiment using the screw holes 102. Further, the screws 103 are used as the heat dissipation fins, and thus, a surface area of heat dissipation can be increased compared to related art in which pin fins are used, so that it is possible to improve heat dissipation.

As described above in the first to the fourth embodiments, according to the present disclosure, it is possible to provide the heatsink 100 capable of easily adjusting heat dissipation characteristics and capable of easily and reliably fixing fins and a base.

### Fifth Embodiment

FIG. 5 is a configuration diagram illustrating a semiconductor device 500 in related art according to a comparative example of the present disclosure. As illustrated in FIG. 5, the semiconductor device 500 in related art includes a semiconductor module 504 as a heating element and a heatsink 520 in related art. The heatsink 520 in related art includes a base 521 and heat dissipation fins 522 integrated with the base 521. The heatsink 520 in related art is fixed at the semiconductor module 504 through a heat dissipation sheet 503 or grease.

A high temperature region 506 of the semiconductor module 504 is a region where a temperature is particularly high in the semiconductor module 504. The high temperature region 506 includes, for example, a heat generating chip 505, and the like. Alternatively, a heat spreader, and the like, for transferring heat from the semiconductor module are positioned. In the semiconductor device 500 in related art, heat dissipation of the heatsink 520 is increased by increasing the number of the heat dissipation fins 522 near the high temperature region 506. Note that in the following description, a region that is not the high temperature region 506 in the semiconductor module 504 will be referred to as a normal region 507.

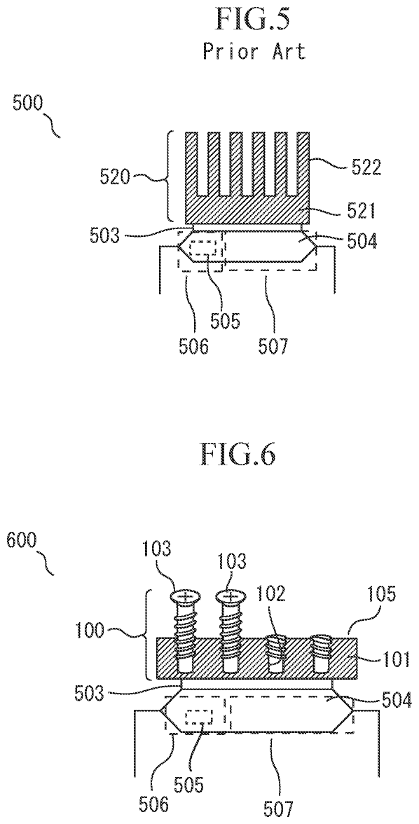

FIG. 6 is a configuration diagram illustrating a semiconductor device 600 according to a fifth embodiment of the present disclosure. In the semiconductor device 600, the heatsink 520 in related art described in FIG. 5 is changed to the heatsink 100 described in the first embodiment.

In the present embodiment, by concentratively positioning the screw holes 102 near the high temperature region 506 of the semiconductor module 504 to increase density of the screws 103 compared to the normal region 507, heat dissipation of the heatsink 100 can be improved. Further, by adjusting locations where the screws 103 are to be inserted and lengths of the screws 103, it is possible to prevent the heatsink 100 from interfering with an inner wall of a chassis that stores the semiconductor device 600 or other parts.

As described above, according to the present embodiment, it is possible to provide the semiconductor device 600 capable of easily adjusting heat dissipation characteristics and capable of easily and reliably fixing the fins and the base. Note that effects similar to the above can be obtained also in a case where the heatsink 100 in any of the second to the fourth embodiments as well as the heatsink 100 in the first embodiment is combined with the semiconductor module 504.

Note that the present disclosure is not limited to the above-described embodiments and can be modified in various ways within a range not deviating from the gist in an implementation stage. Further, the respective embodiments can be combined as appropriate, in which case, the combined effects can be obtained.

### Correspondence with Terms Used in Claims

In the claims, the nut insertion hole 202 and the nut insertion groove 303 will be collectively referred to as a nut insertion portion.

Hereinafter, various aspects of the present disclosure will be collectively described as appendixes.

### (Appendix 1)

A heatsink comprising:
a base having a heat dissipation surface that is thermally coupled to a heating element and dissipates heat from the heating element, and a screw hole provided on the heat dissipation surface; and
a screw screwed into the screw hole.

### (Appendix 2)

The heatsink according to appendix 1, wherein a screw head of the screw projects from the heat dissipation surface and does not contact the heat dissipation surface.

### (Appendix 3)

The heatsink according to appendix 1, wherein the screw does not contact other members except the base.

### (Appendix 4)

A heatsink comprising:
a base having a heat dissipation surface that is thermally coupled to a heating element and dissipates heat from the heating element, and a groove provided on the heat dissipation surface; and
a screw whose screw head is inserted into the groove and whose screw tip portion projects from the heat dissipation surface.

### (Appendix 5)

The heatsink according to appendix 4, wherein other members are not screwed with the screw.

### (Appendix 6)

A heatsink comprising:
a base having a heat dissipation surface that is thermally coupled to a heating element and dissipates heat from the heating element, and a nut insertion portion provided on the heat dissipation surface;
a nut inserted into the nut insertion portion; and
a screw screwed into the nut so that a screw head projects from the heat dissipation surface.

### (Appendix 7)

The heatsink according to appendix 6, wherein the screw does not contact other members except the nut.

### (Appendix 8)

The heatsink according to appendix 6, wherein the nut insertion portion is a nut insertion hole into which the nut is to be inserted.

### (Appendix 9)

The heatsink according to appendix 6, wherein the nut insertion portion is a nut insertion groove into which the nut is to be inserted.

### (Appendix 10)

A semiconductor device comprising the heatsink according to any one of appendixes 1 to 9, and a semiconductor module,
wherein the heating element is the semiconductor module.

### (Appendix 11)

The semiconductor device according to appendix 10, wherein
the semiconductor module has a high temperature region with large heat generation, and a normal region not included in the high temperature region, and
the number of the screws per unit area is larger near the high temperature region than near the normal region on the heat dissipation surface of the heatsink.

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2023-65231, filed on Apr. 12, 2023 including specification, claims, drawings and summary, on which the convention priority of the present application is based, is incorporated herein by reference in its entirety.

1. A heatsink comprising:
a base having a heat dissipation surface that is thermally coupled to a heating element and dissipates heat from the heating element, and a screw hole provided on the heat dissipation surface; and
a screw screwed into the screw hole.

2. The heatsink according to claim 1, wherein a screw head of the screw projects from the heat dissipation surface and does not contact the heat dissipation surface.

3. The heatsink according to claim 1, wherein the screw does not contact other members except the base.

4. A heatsink comprising:
a base having a heat dissipation surface that is thermally coupled to a heating element and dissipates heat from the heating element, and a groove provided on the heat dissipation surface; and
a screw whose screw head is inserted into the groove and whose screw tip portion projects from the heat dissipation surface.

5. The heatsink according to claim 4, wherein other members are not screwed with the screw.

6. A heatsink comprising:
a base having a heat dissipation surface that is thermally coupled to a heating element and dissipates heat from the heating element, and a nut insertion portion provided on the heat dissipation surface;
a nut inserted into the nut insertion portion; and
a screw screwed into the nut so that a screw head projects from the heat dissipation surface.

7. The heatsink according to claim 6, wherein the screw does not contact other members except the nut.

8. The heatsink according to claim 6, wherein the nut insertion portion is a nut insertion hole into which the nut is to be inserted.

9. The heatsink according to claim 6, wherein the nut insertion portion is a nut insertion groove into which the nut is to be inserted.

10. A semiconductor device comprising the heatsink according to claim 1, and a semiconductor module,
wherein the heating element is the semiconductor module.

11. The semiconductor device according to claim 10, wherein
the semiconductor module has a high temperature region with large heat generation, and a normal region not included in the high temperature region, and
the number of the screws per unit area is larger near the high temperature region than near the normal region on the heat dissipation surface of the heatsink.

12. A semiconductor device comprising the heatsink according to claim 4, and a semiconductor module,
wherein the heating element is the semiconductor module.

13. The semiconductor device according to claim 12, wherein
the semiconductor module has a high temperature region with large heat generation, and a normal region not included in the high temperature region, and
the number of the screws per unit area is larger near the high temperature region than near the normal region on the heat dissipation surface of the heatsink.

14. A semiconductor device comprising the heatsink according to claim 6, and a semiconductor module,
wherein the heating element is the semiconductor module.

15. The semiconductor device according to claim 14, wherein
the semiconductor module has a high temperature region with large heat generation, and a normal region not included in the high temperature region, and
the number of the screws per unit area is larger near the high temperature region than near the normal region on the heat dissipation surface of the heatsink.

16. A semiconductor device comprising the heatsink according to claim 8, and a semiconductor module,
wherein the heating element is the semiconductor module.

17. The semiconductor device according to claim 16, wherein
the semiconductor module has a high temperature region with large heat generation, and a normal region not included in the high temperature region, and
the number of the screws per unit area is larger near the high temperature region than near the normal region on the heat dissipation surface of the heatsink.

18. A semiconductor device comprising the heatsink according to claim 9, and a semiconductor module,
wherein the heating element is the semiconductor module.

19. The semiconductor device according to claim 18, wherein
the semiconductor module has a high temperature region with large heat generation, and a normal region not included in the high temperature region, and
the number of the screws per unit area is larger near the high temperature region than near the normal region on the heat dissipation surface of the heatsink.
